(19) United States
(12) Patent Application Publication
(10) Pub. No.: US 2009/0097538 A1
(43) Pub. Date: Apr. 16, 2009

(54) Methods And Apparatus For Adaptive Equalization Using Pattern Detection Methods

(76) Inventors: Pervez M. Aziz, Dallas, TX (US); Mohammad S. Mobin, Orefield, PA (US)

Correspondence Address: Ryan, Mason & Lewis, LLP, Suite 205, 1300 Post Road, Fairfield, CT, 06824, US

(21) Appl. No.: 11/870,063

(22) Filed: Oct. 10, 2007

(51) Int. Cl. H03H 7/30

(52) U.S. Cl. 375/232

(57) ABSTRACT

Methods and apparatus are provided for adaptive equalization using pattern detection methods. A signal is equalized by detecting one or more predefined patterns in the signal; and then changing one or more parameters of the equalization, such as an equalization adaptation rate, based on the detected predefined patterns. The equalization adaptation rate can be increased upon the detection of one or more predefined patterns and then gradually reduced to a steady state value. Equalization parameters that have been previously obtained for various patterns can optionally be loaded upon detection of a corresponding pattern The equalization can optionally be suppressed for one or more predefined patterns. The patterns can be detected, for example, by searching for the one or more predefined patterns in the signal, or by performing a statistical correlation of the signal to detect the one or more predefined patterns.

### FIELD OF THE INVENTION

The present invention relates generally to equalization techniques, and more particularly, to techniques for adaptively establishing one or more equalization parameters based on a detected data pattern.

### BACKGROUND OF THE INVENTION

Digital communication receivers must sample an analog waveform and then reliably detect the sampled data Signals arriving at a receiver are typically corrupted by intersymbol interference (ISI), crosstalk, echo, and other noise. Thus, receivers typically equalize the channel, to compensate for such distortions, and decode the encoded signals at increasingly high clock rates. Decision-feedback equalization (DFE) is a widely-used technique for removing intersymbol interference and other noise. For a detailed discussion of decision feedback equalizers, see, for example, R. Gitlin et al., Digital Communication Principles, (Plenum Press 1992) and E. A. Lee and D. G. Messerschmitt, Digital Communications, (Kluwer Academic Press, 1988), each incorporated by reference herein. Generally, decision-feedback equalization utilizes a nonlinear equalizer to equalize the channel using a feedback loop based on previously decided symbols.

It is often desirable to allow for the equalization components to adaptively respond to changes in channel characteristics or ambient conditions, such as temperature and humidity. Adaptation algorithms typically adapt their filter coefficients in accordance with the signal statistics or the signal spectrum. Equalization algorithms will typically converge on a set of filter coefficients that are often dependent on the data pattern. In many applications, the data pattern may change suddenly and the converged equalizer coefficients may no longer be optimal for the new data pattern. Thus, a degradation of bit error performance may be experienced. Eventually, the equalizer will converge to a solution that is optimal for the new data patter; however, this may take a significant amount of time if optimal steady state performance with low adaptation noise is desired.

A need therefore exists fox methods and apparatus for adaptively establishing equalization parameters based on a detected data pattern.

### SUMMARY OF THE INVENTION

Generally, methods and apparatus are provided for adaptive equalization using pattern detection methods. According to one aspect of the invention, a signal is equalized by detecting one or more predefined patterns in the signal; and then changing one or more parameters of the equalization based on the detected predefined patterns. For example, an equalization adaptation rate can be selected based on the detected pattern. The equalization adaptation rate can be increased upon the detection of one or more predefined patterns and then gradually reduced to a steady state value. Equalization parameters that have been previously obtained for various patterns can optionally be loaded upon detection of a corresponding pattern In another variation, the equalization can be suppressed for one or more predefined patterns.

The patterns can be detected, for example, by searching for the one or more predefined patterns in the signal, or by performing a statistical correlation of the signal to detect the one or more predefined patterns. According to another aspect of the invention, a signal is equalized by detecting one or more predefined patterns in the signal using a statistical correlation; and then equalizing the signal using one or more parameters selected based on the detected predefined patterns.

A more complete understanding of the present invention, as well as further features and advantages of the present invention, will be obtained by reference to the following detailed description and drawings.

### BRIEF DESCRIPTION OF THE DRAWINGS

FIG. 1 is a block diagram of a conventional serializer/deserializer communication channel having a channel impairment;

FIG. 2 is a block diagram of a conventional serializer/deserializer communication channel incorporating decision-feedback equalization;

FIGS. 3 and 4 are schematic block diagrams of FIR filters;

FIG. 5 illustrates the adaptation of a conventional equalizer, based on a fixed steady state update rate μₛₛ;

FIG. 6 illustrates the adaptation of an equalizer based on pattern detection in accordance with the present invention;

FIG. 7 is a block diagram illustrating the pattern dependent adaptation for the coefficients of the DFE filter in further detail;

FIG. 8 illustrates the adaptation of an equalizer using one or mole pre-set equalizer settings based on pattern detection in accordance with the present invention; and

FIG. 9 illustrates the suppression of equalizer adaptation based on pattern detection in accordance with the present invention

### DETAILED DESCRIPTION

The present invention provides methods and apparatus for adaptively establishing one or more equalization parameters based on a detected data pattern. According to one aspect of the invention, a change in the data pattern is detected and then the rate at which adaptation takes place soon is increased after the change in data pattern is detected. Once adaptation has taken place over a sufficient amount of time (to allow a quicker convergence to equalizer coefficients that are optimal for the new data pattern), the present invention gradually lowers or gearshifts down the adaptation rate of the equalizer such that the steady state adaptation would still provide optimal steady state performance.

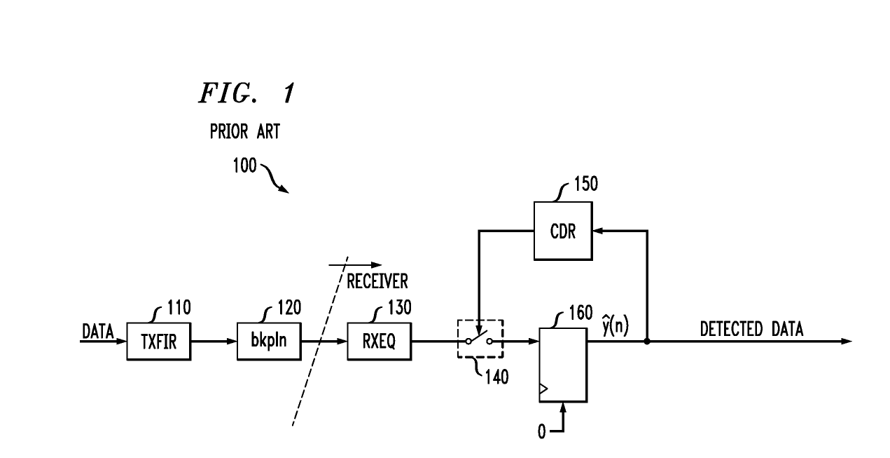

FIG. 1 is a block diagram of a conventional serializer/deserializer communication channel 100 having a channel impairment that is due, for example, to a physical transmission medium such as a backplane or drive head in a magnetic recording system. In the exemplary implementation shown in FIG. 1, the data is transmitted through a backplane channel 120 after optionally being equalized or filtered through a transmit FIR filter (TXFIR) 110. After passing though the backplane 120, the analog signal may optionally be filtered or equalized by a receive equalize (RXEQ) 130 which may consist, for example, of a continuous time filter. The analog signal out of the RXEQ 130 is sampled at the baud late by a switch 140 using a sampling clock generated by a clock/data recovery (CDR) circuit 150. A data detector 160 (or a slicer) digitizes the sample and compares the digitized sample to an exemplary threshold of zero, using the CDR recovered clock.

The phase of the analog waveform is typically unknown and there may be a frequency offset between the frequency at which the original data was transmitted and the nominal receiver sampling clock frequency. The function of the CDR 150 is to properly sample the analog waveform such that when the sampled waveform is passed through a data detector 160, the data is recovered properly despite the fact that the phase and frequency of the transmitted signal is not known. The CDR is often an adaptive feedback circuit and the feedback loop must adjust the phase and frequency of the nominal clock to produce a modified recovered clock that can sample the analog waveform to allow proper data detection.

As previously indicated, the data detector 160 can be implemented as a slicer (i.e., a decision device based on an amplitude threshold) or a more complicated detector such as a sequence detector. For high speed applications, the data detector 160 is often implemented as a slicer that is clocked by the CDR clock. In addition to sampling the data signal, the slicer 160 essentially quantizes the signal to a binary “1” or “0” based on the sampled analog value and a slicer threshold, sₜ If the input to the slicer 160 at time n is w(n), then the output, ŷ(n), of the slicer 160 is given as follows:

$$\hat{y} ( n ) = 1 if w ( n ) > {s}_{t} = 0 otherwise \qquad ( 1 )$$

### DFE Background

As data rates increase for serializer/deserializer applications, the channel quality degrades and the use of decision feedback equalization (DEE) in conjunction with finite impulse response (TXFIR) and receive equalization (RXEQ) filtering will be requited to achieve the bit error rate (BER) performance required by more and more demanding applications Note that the FIR function of the transmitter (TX) might be moved from the transmitter to the receiver (RX) and incorporated into the RXEQ function.

It is noted that the exemplary CDR 150 shown in FIG. 1 is that of a baud rate CDR that makes use of the samples ŷ(n). Other types of CDRs, such as CDRs making use of additional clocked/sampled signals can be used as well, as would be apparent to a person of ordinary skill in the art. See, for example, J. D. H. Alexander, “Clock Recovery From Random Binary Signals,” Electronics Letters, 541-542 (October 1975).

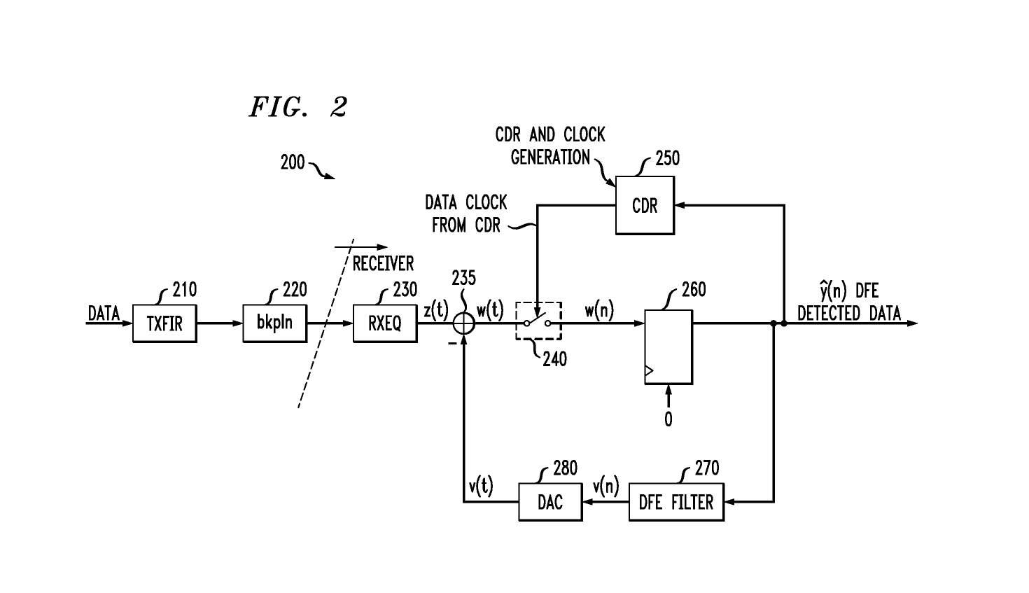

FIG. 2 is a block diagram of a conventional serializer/deserializer communication channel 200 that incorporates a traditional DFE based equalizer 270 in addition to the TX and RX equalization 210, 230 of FIG. 1. As shown in FIG. 2, the data is transmitted through a backplane channel 220 after optionally being equalized or filtered through a transmit FIR filter (TXFIR) 210. After passing though the backplane 220, the analog signal may optionally be filtered or equalized by a receive equalizer (RXEQ) 230 which may consist, for example, of a continuous time filter. The analog signal out of the RXEQ 230 is sampled at the baud rate by a switch 240 using a data clock generated by a clock/data recovery (CDR) circuit 250, in a similar manner to FIG. 1

As discussed hereinafter, a DFE correction, v(t), generated by a DFE filter 270 and digitized by a digital-to-analog converter 280 is subtracted by an analog summer 235 from the output, z(t), of the RXEQ 230 to produce a DFE corrected signal w(t).

w(t)=z(t)−v(t) (2)

Then, the signal w(t) is sampled by a switch 240:

w(n)=w(nT) (3)

with T being the baud period. The sampled signal w(n) is then sliced by a slicer 260 to produce the detected data ŷ(n) The slicer output in turn is used to produce the filtered DFE output v(n) which is converted by the DAC 280 to the continuous time signal v(t). The DFE filter output 280 is given by:

$$v ( n ) = {\sum }_{l = 1}^{L} b ( l ) \hat{y} ( n - l ) \qquad ( 4 )$$

where b(l) represents the coefficients of the L tap DFE.

It is noted that the DFE filter 270 uses as its input past data decisions starting at ŷ(n−1) and earlier (it does not use the current decision ŷ(n)). This guarantees that the operation is causal. The CDR 250 is again shown as a baud late sampled CDR but could be an oversampled CDR, as in U.S. patent application Ser. No. 11/356,691, filed Feb. 17, 2006, entitled “Method And Apparatus For Generating One Or More Clock Signals For A Decision Feedback Equalizer Using DFE Detected Data”, incorporated by reference herein, where a number of variants are disclosed.

### Adaptive Equalization

An adaptive CDR is often an important component of any communications receiver. Equally important, however, are the equalization components. Equalization refers to shaping the signal spectrum or equivalently time domain samples to some desired spectrum or amplitude sample targets respectively. In the conventional block diagram of FIG. 1, equalization is performed by the transmit filter (TXFIR) 110 which in this case is a finite impulse response (FIR) filter. It is also per formed by the receive equalizer (RXEQ) 130.

In the illustrative embodiment discussed herein, NRZ equalization targets are employed, i.e., transmitted data bits 1,0 with signed values 1,−1 should be equalized to received target values of 1 and −1. In the frequency domain, this means that the equalized signal magnitude spectrum should be shaped to have a flat all pass gain at least until the Nyquist frequency which is half of the baud frequency. The present invention could be extended for other equalization targets such as partial response (PR) targets or pulse amplitude modulation (PAM), as would be apparent to a person of ordinary skill in the art. It is often desirable to allow for the equalization components to be adaptive to respond to changes in channel (e.g., backplane) characteristics or ambient conditions, such as temperature and humidity.

As indicated above, the present invention recognizes that adaptation algorithms adapt their filter coefficients in accordance with the statistics or equivalently the spectrum of the signal based on which it adapts the coefficients, i.e., the filter coefficients that the algorithm converges to are dependent on the data pattern that the algorithm adapts on. In many applications, the data pattern may change suddenly and as such the converged equalizer coefficients may not be optimal for the new data pattern and result in a degradation of bit error performance. Eventually, the equalizer will converge to a solution that is optimal for the new data pattern; however, this may take a significant amount of time if optimal steady state performance with low adaptation noise is desired. The present invention combats the above problem. In another situation, there could appear some patterns that could be harmful to the adaptation behavior. In this case, one would want to freeze the updates of the equalizer coefficients until the deleterious pattern was no longer detected

### Adaptation Rate Control

The present invention detects a change in the data pattern and then increases the rate at which adaptation takes place soon after the change in data pattern is detected Once adaptation has taken place over a sufficient amount of time (to allow a quicker convergence to equalizer coefficients that are optimal for the new data pattern), the present invention gradually lowers or gearshifts down the adaptation rate of the equalizer such that the steady state adaptation would still provide optimal steady state performance.

Generic LMS/ZF Algorithm

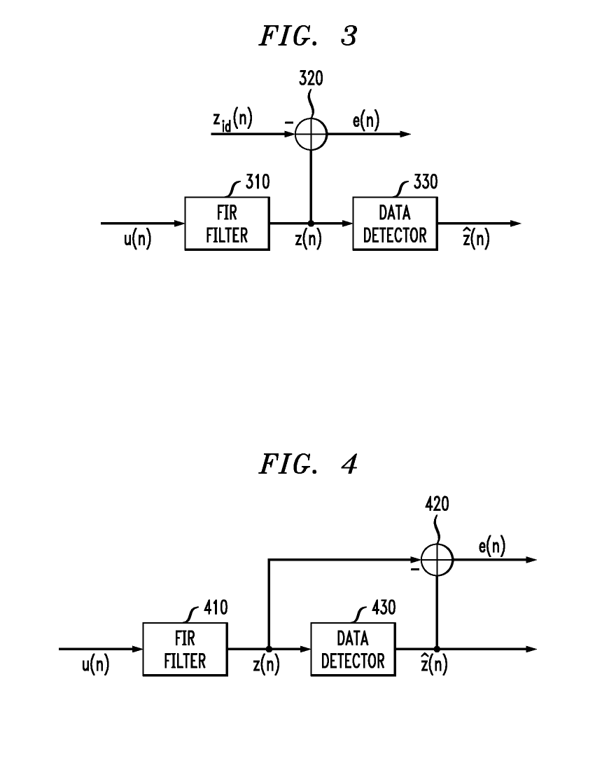

The well known least mean square (LMS) is used to illustrate the change in adaptation rate LMS type algorithms are convenient methods to adapt filter coefficients. Consider a generic FIR filter 310 as shown in FIG. 3. FIG. 3 is a schematic block diagram of a first embodiment of an FIR filter. The FIR filter 310 has input signal u(n) and output signal y(n). If h(n) are the filter coefficients of the FIR filter 310, then the output of the FIR filter 310 can be expressed as:

$$z ( n ) = {\sum }_{l = 0}^{l = L - 1} h ( l ) u ( n - l ) \qquad ( 5 )$$

An “error” term at the filter output can be computed based on known ideal values of the output z_{id}(n), referred to as ideal decision error generation. This implementation may be of value, for example, in a practical system during a training period if the receiver knows apriori the data being transmitted. An adder 320 generates an error signal, e(n), that represents an error term at the filter output The error signal, e(n), may be expressed as follows:

e(n)=z(n)−z_{id}(n)

where z_{id}(n) is the known output values and z(n) is the output of the FIR filter 310 A data detector 430 detects the data, \hat{z}(n).

FIG. 4 is a schematic block diagram of a second embodiment of the error generation for an FIR filter 410. The “error” term at the filter output can also be computed based on estimated ideal values \hat{z}(n), referred to as decision driven error generation. An adder 420 generates an error signal, e(n), that represents an error term at the filter output. The error signal, e(n), may be expressed as follows:

e(n)=z(n)−\hat{z}(n).

where \hat{z}(n) is the data detected by a data detector 430.

The LMS algorithm adapts the l th tap at time n as follows;

h(n,l)=h(n−1,l)+μe(n)u(n−l) (6)

For a more detailed discussion of the LMS algorithm, see, for example, S. Haykin, “Communication Systems,” John Wiley and Sons (1992).

A variant of the LMS algorithm is the so called Zero Forcing (ZF) algorithm, which drives the adaptation based on the filter outputs instead of the filter input.

h(n,l)=h(n−1,l)+μe(n)z(n−l) (7)

Pattern Detection Based Rate Control

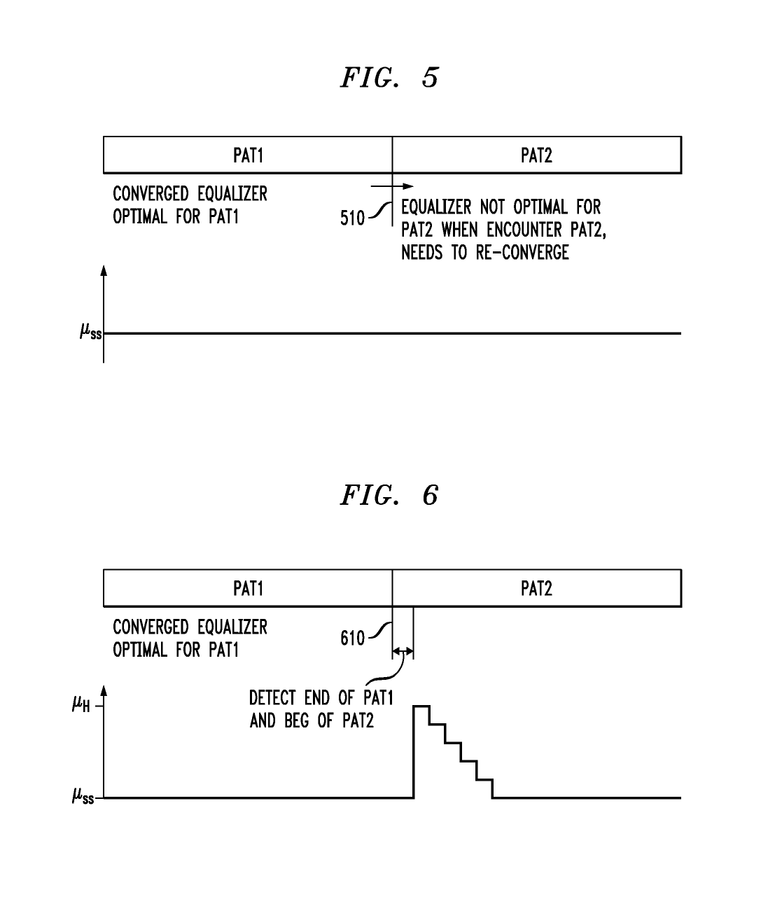

FIG. 5 illustrates the adaptation of a conventional equalizer, such as the equalizer 110, 130 of FIG. 1, based on a fixed steady state update rate μₛₛ. As shown in FIG. 5, when another pattern, PAT2 is encountered at a time 510, the equalizer 110, 130 must re-converge to a solution that is now optimal for PAT2. However, with a conventional equalizer; this may take a prolonged amount of time, especially since it is typically desired to keep μₛₛ low to minimize adaptation jitter or noise. In the extended time that it takes to adapt the equalizer, the non-optimal equalizer setting may degrade the bit error rate performance of the detected data based on the non-optimal setting

FIG. 6 illustrates the adaptation of an equalizer based on pattern detection in accordance with the present invention. Initially, the adaptation rate, μ, is set to a maximum value, μ_{H}. As shown in FIG. 6, the beginning of a new data pattern is detected at a time 610, and then the adaptation rate, μ, is set to some higher value, μ_{H}, corresponding to a faster adaptation rate. The adaptation rate can then be gradually gearshifted down to some smaller steady state value μₛₛ. The profile of the gearshifting may be optimized based on a given application, as would be apparent to a person of ordinary skill in the art Although the pattern may not be detected instantaneously, as shown by the finite detection time in FIG. 6, the time needed to detect the change in pattern will be much smaller than would have been needed to allow the equalizer to re-converge using the smaller μₛₛ.

Adaptation Signals for Exemplary Equalization Scenarios

The adaptation late can be adjusted for either the transmit filter 210, the DFE filter 270 or a receive filter 230. For example, consider that the equalizer being adapted is a filter in the RXEQ 230. Then, the ZF valiant of the LMS can be used by considering z(n)=s(n) and e(n)=w(n)−ŷ(n). For LMS based DFE adaptation, e(n)=w(n)−ŷ(n) and u(n)=ŷ(n). Note that the operation of the DEL filter 270 in conjunction with the feedback loop is not strictly a linear filtering operation and the error measured is not at the output of the DEE filter. However, the DFE filter still adapts well using the error at the input of the slicer 260 since that is where we desire to minimize the error Likewise, the RXEQ filter 230 filter adapts well using the error at the input of tire slicer 260. It is noted that in an implementation that does not contain the DFE filter 270, the output of the RXEQ filter 230 equals the input of the slicer 260

Also note that in FIGS. 3 and 4, the error is shown to be calculated based on an analog subtraction. However, alternate forms of the error may be obtained in a manner that makes it more practical for implementation. For example, using additional slicers with thresholds at appropriate signal levels, the sign of the en or may be computed Likewise, the sign of the generic adaptation signal z(n) may be used. In particular, a sign-sign adaptation can be used and the generic LMS or ZF equations are modified to become:

h(n,l)=h(n−1,l)+μsign[(e(n)]sign[u(n−l)] (8)

h(n,l)=h(n−1,l)+μsign[e(n)]sign[z(n−l)] (9)

For the above DFE case, the LMS adaptation term sign[u(n)] is already obtained naturally as ŷ(n) since the DEE latch detecting w(n) is a slicer with a two level output.

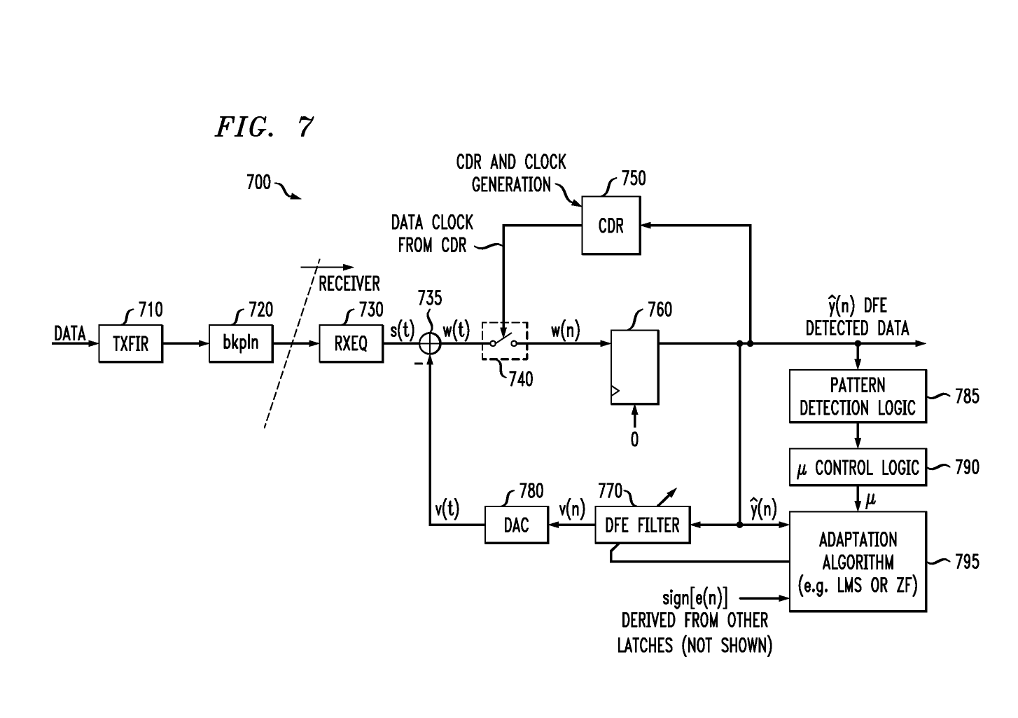

FIG. 7 is a block diagram illustrating the pattern dependent adaptation for the coefficients of the DEE filter in further detail. Elements 710, 720, 730, 735, 740, 750, 760, 770, 780 may be implemented in a similar manner to the corresponding elements of FIG. 2. In addition, as shown in FIG. 7, the serializer/deserializer 700 includes pattern detection logic 785, adaptation rate control logic 790 and an adaptation algorithm 795.

Potential implementations for the pattern detection logic 785 are discussed below in a section entitled “Pattern Detection Methods.” The adaptation late control logic 790 varies the adapation rate, for example, between μ_{H} and μ_{SS}. As indicated above, the exemplary adaptation algorithm 795 may be implemented as the LMS or ZF algorithms. As shown in FIG. 7, the adaptation algorithm 795 processes the current decision ŷ(n) and the sign of the error signal e(n) to generate the coefficients for the DFE Filter 770.

### Equalizer Pie-Set Control

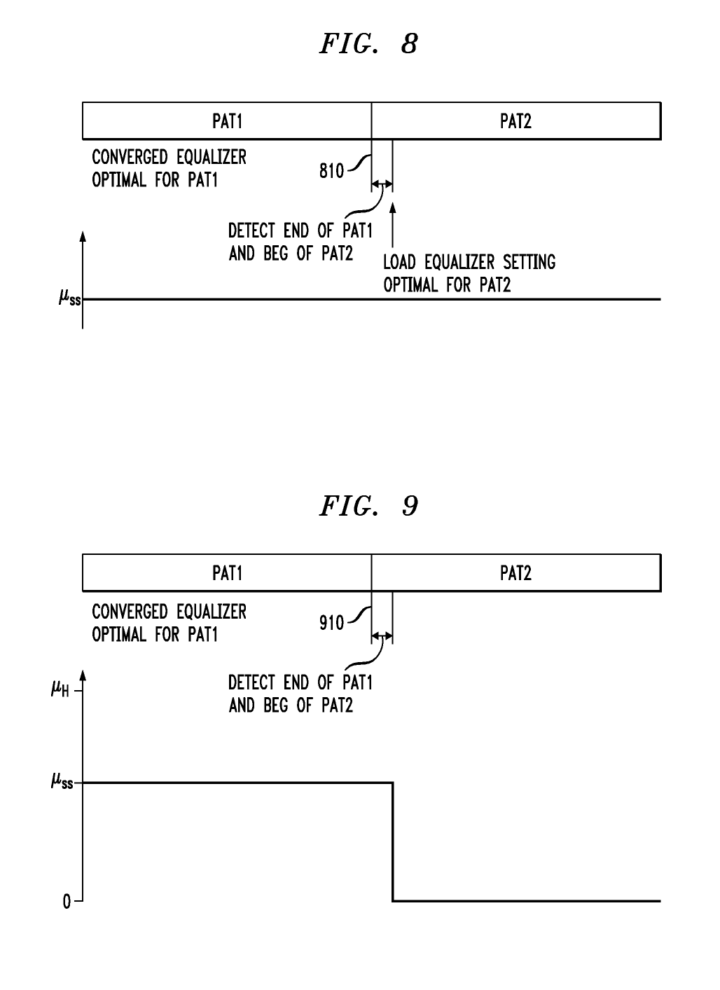

In cases when the expected patterns are known apriori and consist of a finite number of predefined patterns, it is possible to pre-set an equalizer that has been apriori determined to work well with the corresponding pattern. FIG. 8 illustrates the adaptation of an equalizer using one or more pre-set equalizer settings based on pattern detection in accordance with the present invention. Once the beginning of the predefined pattern is detected at a time 810, the corresponding equalizer settings are loaded, for example, from a data store. Subsequent adaptation may still occur at the relatively slower updated late of μₛₛ to account for environmental variations, such as ambient temperature. For pre-set control, FIG. 7 can be modified to appropriately reflect the equalizer pre-set instead of μ control 790.

For example, in a Fiber Channel standard, a 40 bit apriori known idle pattern is often transmitted. When user data is subsequently transmitted, the receiver will typically detect a random type pattern. The receiver may switch between equalizer settings optimal for the idle pattern when the idle pattern is transmitted and equalizer settings that are optimal for the random data when the random data is transmitted.

### Adaptation Suppression

FIG. 9 illustrates the suppression of equalizer adaptation based on pattern detection in accordance with the present invention. In certain situations, the presence of certain patterns (detected in FIG. 9 at a time 910) may actually be harmful in driving the equalizer convergence algorithms to undesirable solutions for more typical or user patterns that might be transmitted. For example, tone type patterns, such as the Nyquist or 1I pattern (1,0,1,0, . . . ), 2T, (1,1,0,0,1,1,0,0 . . . ) may lead to undesirable equalization convergence. For applications where such (or other) special patterns may be transmitted for other reasons (e.g., link diagnostic or CDR training), one could detect any finite set of specific patterns easily and disable or suppress equalizer adaptation during the duration of these patterns by setting μ to 0. A periodic pattern with a very short period may also be harmful for adaptive equalizer convergence. A periodic pattern detector based on auto-con elation of the data stream can be an indicator to suppress the adaptation.

### Pattern Detection Methods

Pattern detection can be done in a number of ways, as considered below

Pattern Search

In some applications, specific patterns may be transmitted. For example, in the Fiber Channel standard mentioned above, an apriori known 40 bit pattern is transmitted repeatedly during an “idle period.” Thus, in the context of the present invention, PAT1 can be considered to be the repeated concatenation of this 40 bit pattern. After the “idle” period actual user data is transmitted and can be considered to be PAT2. One way to detect transitions between PAT1 and PAT2 (or vice-versa) is for a pattern detector to search the received detected data stream for this 40 bit pattern. Once the pattern detector no longer detects the data stream (to within some pre-programmed tolerance to account for any bit errors), it can be decided that user data is now being transmitted (PAT2) and the equalizer adaptation rate μ should be switched to μ_{H} and gearshifting enabled.

In another scenario, simple tone detectors are used to search for occurrences of for example, 1T, 2T and 3T patterns of up to a certain length and adaptation can be suppressed upon the detection of any one of these patterns. Once the pattern is no longer detected, the adaptation can resume

Statistical or Period Detection

In applications where the nature of transmitted patterns may not be known apriori, one can resort to statistical techniques to detect the transition from pattern to pattern. For example, consider an application that transmits a fixed length idle pattern but does not always transmit the same 40 bit pattern during the idle. In other words, PAT1 would not consist of a concatenation of the same 40 bit pattern but multiple segments where one idle pattern was transmitted for a certain duration, then another; then another until the randomized user data was transmitted. In this case, it may be prohibitive to have a pattern searching detector search for a potentially large number of idle patterns. However; one could detect the presence of this idle pattern in one of several ways. For example, explicit period determination can be used, i.e., note whether the same pattern is being received every 40 bits. The second technique is to use a statistical auto-correlation. Either of these techniques will identify the presence of a periodic pattern and will identify the transition to the user data A third method is to initially use a statistical autocorrelation method during which time the boundary between exemplary 40 bit patterns awe determined. Once the bit boundaries are determined, explicit period detection can be used in a more computationally efficient way then attempting to do this without initial boundary detection.

It is to be understood that the embodiments and variations shown and described herein are merely illustrative of the principles of this invention and that various modifications may be implemented by those skilled in the art without departing from the scope and spirit of the invention.

For example, the present invention can be performed with other implementations of the DFE equalizer such as threshold based look ahead/precompute type implementations instead of an analog summing implementation of the DFE equalizer.

We claim:

1. A method for equalizing a signal, comprising:
detecting one or more predefined patterns in said signal; and
changing one or more parameters of said equalization based on said detected predefined patterns.

2. The method of claim 1, wherein said changing step Hither comprises the step of changing an equalization adaptation late.

3. The method of claim 2, wherein said equalization adaptation rate is increased upon said detection of one or mole predefined patterns and then gradually reduced to a steady state value.

4. The method of claim 1, wherein said changing step further comprises the step of loading one or more equalization parameters previously obtained for said one or more predefined patterns.

5. The method of claim 1, wherein said changing step further comprises the step of suppressing said equalization for one or more predefined patterns.

6. The method of claim 1, wherein said detecting step further comprises the step of searching for said one or more predefined patterns in said signal.

7. The method of claim 1, wherein said detecting step further comprises the step of performing a statistical correlation of said signal to detect said one or mole predefined patterns.

8. The method of claim 1, wherein said equalization is performed in a transmitter of said signal.

9. The method of claim 1, wherein said equalization is performed in a receiver of said signal.

10. A method for equalizing a signal, comprising:
detecting one or more predefined patterns in said signal using a statistical correlation; and
equalizing said signal using one or more parameters selected based on said detected predefined patterns.

11. The method of claim 10, wherein said equalizing step further comprises the step of changing an equalization adaptation rate.

12. The method of claim 11, wherein said equalization adaptation rate is increased upon said detection of one or more predefined patterns and then gradually reduced to a steady state value.

13. The method of claim 10, wherein said equalizing step further comprises the step of loading one or more equalization parameters previously obtained fox said one or more predefined patterns

14. The method of claim 10, wherein said equalization is performed in a transmitter of said signal.

15. The method of claim 10, wherein said equalization is performed in a receiver of said signal.

16. A signal processor for equalizing a signal, comprising:
a pattern detector for detecting one or more predefined patterns in said signal; and
a controller for changing one or more parameters of said equalization based on said detected predefined patterns.

17. The signal processor of claim 16, wherein said controller is further configured to change an equalization adaptation rate.

18. The signal processor of claim 16, wherein said controller is further configured to load one or more equalization parameters previously obtained for said one or more predefined patterns.

19. The signal processor of claim 16, wherein said controller is further configured to suppress said equalization for one or more predefined patterns.

20. The signal processor of claim 16, wherein said pattern detector is further configured to search for said one or more predefined patterns in said signal.

21. The signal processor of claim 16, wherein said pattern detector is further configured to perform a statistical correlation of said signal to detect said one or more predefined patterns.

22. A signal processor for equalizing a signal, comprising:
a pattern detector for detecting one or more predefined patterns in said signal using statistical correlation; and
an equalizer for equalizing said signal using one or more parameters selected based on said detected predefined patterns.

23. The signal processor of claim 22, wherein said equalizer is further configured to change an equalization adaptation rate.

24. The signal processor of claim 22, wherein said equalizer is further configured to load one or more equalization parameters previously obtained for said one or more predefined patterns.
